(19) United States
(12) Patent Application Publication
(10) Pub. No.: US 2016/0319139 A1
(43) Pub. Date: Nov. 3, 2016

(54) SELF HEALING SILICA BASED DIELECTRIC INK FOR PRINTED ELECTRONIC APPLICATIONS

(71) Applicant: COUNCIL OF SCIENTIFIC & INDUSTRIAL RESEARCH, New Delhi (IN)

(72) Inventors: Kuzhichalil Peethambharan Surendran, Thiruvananthapuram (IN); Mailadil Thomas Sebastian, Thiruvananthapuram (IN); Jobin Varghese, Thiruvananthapuram (IN)

(21) Appl. No.: 15/103,719

(22) PCT Filed: Dec. 10, 2014
(86) PCT No.: PCT/IN2014/000766

§ 371 Date: Jun. 10, 2016

(30) Foreign Application Priority Data
Dec. 12, 2013 (IN) 3620/DEL/2013

(51) Int. Cl. C09D 11/037; C09D 11/033; H05K 1/02; C09D 11/106

(52) U.S. Cl. CPC C09D 11/037; C09D 11/106; C09D 11/033; H05K 1/024; H05K 1/028

(57) ABSTRACT

The present invention relates to self healing silica based dielectric ink for printed electronic applications. Novel self healing silica based dielectric ink screen printable on flexible substrates is indigenously developed for printed electronic applications. The silica ink consist of solvent system (Xylene/Ethanol), a filler (55-65 wt. % of SiO2 with respect to solvent system), a dispersant (0.8-1.2 wt. % of natural fish oil with respect to filler) and a binder (4-6 wt. % of Polyvinyl Butyral with respect to filler). The colloidal ink comprises of silica as the major filler with suitable organic vehicles. The present invention of silica ink is advantageous over water based dielectric inks in terms of faster curing time. Thixotropic behavior of the colloidal silica ink is optimized based on screen printing technique. Solvent mixture, natural dispersant, polymer binder etc. played a key role in controlling the colloidal stability of the ink. The microstructure and surface roughness of printed dielectric silica ink on Mylar film was investigated. The radio and microwave dielectric properties are also investigated for the optimized silica ink. The best dielectric properties, fast curing and printability of the developed silica ink make it a suitable candidate for dye-sensitized solar cell applications also.

### FIELD OF THE INVENTION

The present invention relates to a self healing silica based low k (relative permittivity, k is also denoted as ∈ᵣ) dielectric ink for printed electronic applications. Particularly, present invention relates to a self healing silica based dielectric ink, screen printable on flexible substrates is indigenously developed for printed electronic applications.

### BACKGROUND AND PRIOR ART OF THE INVENTION

The printed electronics is expected to increase its market share significantly in the near future. This technology has found use in a plethora of applications ranging from displays and lighting to RFIDs (Radio Frequency Identification), sensors, solar cells and batteries. Increased miniaturization, technological changes, and portability needs of electronic products in different sectors such as telecommunications, packaging, automotive, and medicine are driving the demand for flexible electronic products in the market.

The global printed electronics market is expected to grow from $2.8 billion in 2008 to $24.25 billion in 2015, at a Compound Annual Growth Rate (CAGR) of 38.4% from 2010 to 2015. Interestingly the printed electronics market in Asia-Pacific is expected to grow fastest at a CAGR of 40.8% from 2010 to 2015 as forecasted by Markets and Markets Research Publication (SE 1222), Dallas, 2011. The projected multibillion dollar market for low cost printing technologies is catalysed by meticulous efforts from scientific community towards the development of cost effective grooming methods of printing ink.

The emerging trends in the microelectronics have been towards smaller features, lower prices, increased operational frequencies and more reliable products, which opens up new applications for smaller gadgets with circuits printed essentially on flexible substrates. In principle, printed electronic circuits (PEC) involves direct screen printing or inkjet printing process using conductive (or dielectric) paste on flexible substrates and hence eliminate the required traditional subtractive wet process used in “silicon electronics” today, which includes etching, stripping, metallization and copper plating. In conventional “silicon electronics” each conductor (or dielectric) layer is added as a full sheet (thin film), which is then photo-lithographically etched to generate the desired circuits. This is a time consuming process in itself, sometimes requiring high vacuum, and material wastage is >90%. This adds costs from both the excess material and disposal of the waste material. On the other hand printed electronic circuit uses about 20% of the current labour requirement by the traditional method.

The conventional applications of ceramic ink include decoration of ceramic tiles, dinnerware and 3D printing. In printed electronics various printing methods such as inkjet, gravure and screen printing were suggested for patterning conductive, semiconductive and insulating materials. For the application of printing technologies in electronics manufacturing, inks or pastes composed of nanoparticles, solvent and additives are basically needed. High k materials in ink form are increasingly used in antennae, DRAM Capacitors, MLC circuits, micro-actuators, high efficiency pulse power capacitors, and solid state cooling devices.

Reference may be made to journal by Zhou et al. Transactions of Nonferrous Metals Society of China 2008, vol. 18, 150-154, wherein barium titanate (BaTiO₃) ceramic ink for continuous ink-jet printing where filler powder is synthesized by mechanical mixing and sol-gel method. BaTiO₃ powder was grounded with various amount of dispersant polypropylene acid, conductivity salt (ammonium nitrate) and provisional binder (polyvinylbutyral) in deionized water in a conventional ball mill for 36 h.

The rheology of ZrO₂/Al₂O₃ ceramic ink and spread of ink droplets for direct ink-jet printing was reported by Prakasan et al. Journal of Material Processing Technology, 2006, vol. 176, 222-229. This paper describes the ceramic ink colloidal stability for ink-jet printing. The above references provide evidence to the ceramic ink preparation and the rheological characteristics of different ceramic ink used for ink-jet printing. However the authors made no attempt on the colloidal stability of the ceramic ink for low cost screen printing applications.

Reference may be made to pigment preparation and its use especially in printing ink, pigment preparation which comprises coated and uncoated SiO₂ flakes, one or more special effect pigment and phosphate compound reported by Schoen et al. U.S. patent 2004, U.S. Pat. No. 6,702,885 B2. The major components of printing ink consist of binder, pigment, dye and additives. The application of printed products is used for printing packages, labels and high quality journals. However, as evident from the above references, the developed coated silica flakes in colloidal suspension are suitable for textile printing industry and there was no mention on the adaptability of these inks in printed electronics.

Reference may be made to the nano SiO₂ particle that were dispersed in an organic solvent with additives to make SiO₂ ink reported by Kim et al. Microelectronic Engineering, 2011, vol. 88, 797. In this investigation, two types of dispersing agents were attempted: polyvinylpyrrolidone (PVP) and hydroxypropylcellulose (HPC). The solvents were ethylene glycol and ethanol to which a small amount of PVP and HPC was added to prevent the aggregation of SiO₂. However, as evident from the above references that their intention was to prepare a nano silica ink dispersion and printed onto a Si substrate. In order to evaluate the feasibility of the SiO₂ films for a passivation layer, a conductive coplanar waveguide (CPW) pattern of silver was also printed on the coated SiO₂ film followed by heat treatment at above 200° C. In the above article also, no attempt has been made to print silica on flexible substrate at room temperature.

Reference may be made to the implementation of tape casting as a manufacturing process for the production of thin sheets of ceramic materials patented by Glenn Howatt, U.S. Pat. No. 2,582,993, 1952. The tape casting technique has been limited to two dimensional structures with thickness greater than 100 microns. The screen printing technique in electronics was started by IBM in 1960. The limitations of LTCC technology such as tape lamination, 3D structure printing and design flexibility can be compensated with screen printing technique in modern electronics. Thick film (screen printed), LTCC structure together with soldering can be used to make hermetic packages.

As evident from the above references, the screen printing inks have more attraction in near future in various cost effective fabrication of electronic modules. Screen printing is chosen as the printing technique in electronic printing processes since it is rather cheaper, consumes little material with minimal wastage and is important in circuit printing. Furthermore, screen printing offers much flexibility for rapid prototyping and can be applied as a final process stage towards customized electronic applications. In typical screen printing, thick pastes of ink with optimal viscosity ranging from 0.1 to 50 Pa·s are being used. The ink must be compatible and should be wetting uniformly to the substrate to decrease its contact angle.

Reference may be made to the dielectric SiO₂ ink and its various applications in the present and future technologies. The most of the thin film transistor (TFT) reported by Xuejun Lu et. al. Applied Physics Letters, 2008, vol. 93, 243301, and organic thin film transistors reported by Lee et al. Applied Physics Letters, 2009, vol. 94, 122105, are made up of SiO₂ as a gate dielectric because of its low permittivity, low dissipation factor and high abundance on earth. Thin film transistor for display applications uses, SiO₂ as gate materials having 200 nm thickness reported by Kwang song et al. Synthetic Metals, 2009, vol. 159, 1381-1385. TiO₂ ceramic ink for silicon solar cell anti-reflection coating prepared by conventional thick film printing method is described by Szlufcik et al. Solar Energy Materials, 1989, vol. 18, 241-252. The optimum ink composition consists of TiO₂ ceramic filler, with terpinol, ethyl cellulose, butanol as the organic vehicle. The Titania ink is printed onto polished silicon wafer. However, as evident from the above references that dielectric silica ink are having more attractive applications in the present and future technology solutions. The improvement in the performances of dye-sensitized solar cell with SiO₂ coated TiO₂ photoelectrode was reported by Mohan et. al. Journal of Nanoscience and Nanotechnology, 2012, vol. 12, 433-438. The porous SiO₂ was coated by spraying and it improves the photocurrent density of the dye-sensitized solar cell. However, development of room temperature curable silica dielectric ink is yet to be made which is undertaken in the present invention.

The present invention of silica ink is advantageous over water based dielectric inks in terms of faster curing time. Thixotropic behavior of the colloidal silica ink is optimized based on screen printing technique. Solvent mixture, natural dispersant, polymer binder etc. play a key role in controlling the colloidal stability of the ink. The microstructure and surface roughness of printed dielectric silica ink on Mylar (biaxially-oriented polyethylene terephthalate or BoPET) substrate were investigated. The radio and microwave dielectric properties were also investigated for the optimized silica ink after screen printing on Mylar substrate.

### OBJECTIVES OF THE INVENTION

The main objective of the present invention is to develop a self healing silica based low k dielectric ink for flexible printed electronic applications.

Another objective of the present invention is to bring down the healing temperature of dielectric silica ink to room temperature by employing suitable organic vehicle and faster curing.

Yet another objective of the present invention is to retain low relative permittivity of the dielectric ink after removal of the solvent.

Still another objective of the present invention is to develop a suitable polymer binder system which does not degrade the chemico-physical properties of the silica ink.

Yet another objective of the present invention is to develop low cost, and high production volume technique for the synthesis of dielectric silica ink.

Yet another objective of the present invention is to achieve high thermal stability of relative permittivity of the colloidal ink when printed on a flexible substrate.

Yet another objective of the present invention is the long shelf life, ideal flow characteristics and high colloidal stability of the developed ink.

Yet another objective of the present invention is the versatility of the colloidal ink to different type of substrate such as flexible and rigid.

Yet another objective of the present invention is the accurate registration and multilayer printing process.

### SUMMARY OF THE INVENTION

Accordingly, present invention provides a self healing silica based dielectric ink comprising; 85-95 wt. % silica based colloidal suspension, 0.8-1.2 wt. % dispersant and 5-15 wt. % polymeric binder, wherein said ink is useful for flexible printed electronic applications.

In an embodiment of the present invention, the self healing silica based dielectric ink exhibit the relative permittivity (k) ∈ᵣ in the range of 2.4 to 3.8 and 2.0 to 2.8 and dielectric loss (tan δ) in the range of 0.01 to 0.05 and 0.002 to 0.006 at 1 MHz and at 15.15 GHz respectively.

In yet another embodiment of the present invention, printed silica ink shows temperature variation of relative permittivity in the range of 55-65 ppm/° C. at operating temperature 25 to 60° C.

In yet another embodiment, the present invention provides a process for the preparation of the silica based dielectric ink comprising the steps of:
i. preheating SiO₂ powder at 400 to 700° C. for 3 to 5 hours to obtain a preheated SiO₂ powder;
ii. ball milling the 55 to 65 wt. % preheated SiO₂ powder for a period in the range of 12 to 24 hours with 30-40 wt. % solvent and 0.8-1.2 wt. % dispersant to obtain a ball milled mixture;
iii. adding 4-6 wt. % binder in the ball milled mixture as obtained in step (ii) followed by milling for 12-24 hours to obtain silica based dielectric ink.

In yet another embodiment of the present invention, the solvent used is selected from ethanol or xylene.

In yet another embodiment of the present invention, the dispersant used is fish oil.

In yet another embodiment of the present invention, the binder used is Polyvinyl Butyral (Butvar B-98).

In yet another embodiment of the present invention, the viscosity of the ink with respect to shear rate is in the range of 1.5 to 10 Pa·s.

In an embodiment of the present invention, the self healing dielectric silica ink is formulated with suitable organic vehicles.

In yet another embodiment of the present invention, said ink is useful for screen printed on rigid glass substrate and flexible mylar substrates.

In yet another embodiment of the present invention, said non aqueous dielectric silica ink is with self healing effect during printing process.

In yet another embodiment, the solvent of the ink solution evaporates at a faster rate for a precise print accuracy.

In yet another embodiment of the present invention the silica ink have good adhesion to flexible and hard substrates.

### BRIEF DESCRIPTION OF THE DRAWINGS

FIG. 1 Room temperature x-ray diffraction pattern of preheated SiO₂ particle.

FIG. 2 Microstructure and particle size distribution at different concentration of ground SiO₂ particle.

FIG. 3 Optimization of dispersant by rheological studies.

FIG. 4 Optimization of the dispersant by sedimentation analysis.

FIG. 5 Optimization of silica filler content by rheological studies.

FIG. 6 Optimization of the binder by rheological studies.

FIG. 7 The silica ink with optimal rheological properties.

FIG. 8 Steps of ink formulation.

FIG. 9 Steps of screen preparation.

FIG. 10 Photographs of screen, silica ink on flexible and rigid surfaces.

FIG. 11 Optical images of dielectric silica ink before printing optimization.

FIG. 12 Optical images of multiple printing of dielectric silica ink after printing optimization.

FIG. 13 Interfaces of Mylar and dielectric silica ink images by optical microscopy.

FIG. 14 Microstructure of dielectric silica ink.

FIG. 15 Microstructure interfaces of dielectric silica ink and Mylar sheet.

FIG. 16 Atomic force microscopy images of printed dielectric ink and Mylar sheet surfaces.

FIG. 17 Radio frequency studies of dielectric silica ink.

FIG. 18 Temperature variation of relative permittivity of dielectric silica ink and Mylar sheet.

### DETAILED DESCRIPTION OF THE INVENTION

Present invention provides a low cost preparation process for dielectric silica ink screen printed on various substrates. The dielectric silica ink has low loss and low relative permittivity which is more suitable for the printed microwave circuit applications. The dielectric ink with multiple solvent systems leads to the self healing effect of dielectric silica ink. The present invention relates to a self healing silica based low k dielectric ink for printed electronic circuits. Novel self healing silica based dielectric ink screen printable on flexible substrates is indigenously developed for high frequency printed electronics circuits. The silica ink consist of a solvent system (Xylene/Ethanol), a filler (55-65 wt. % of SiO₂ with respect to solvent system), a dispersant (0.8-1.2 wt. % of natural fish oil with respect to filler) and a binder (4-6 wt. % of Polyvinyl Butyral with respect to filler). The colloidal ink comprises of silica as the dielectric filler with suitable organic vehicles. The present invention of silica ink is advantageous over water based dielectric inks in terms of ease of synthesis, cost effectiveness and room temperature curing.

Thixotropic behavior of the colloidal silica ink is optimized based on screen printing technique. Solvent mixture, natural dispersant, polymer binder etc. played a key role in controlling the colloidal stability of the ink. The radio and microwave dielectric properties are investigated for the optimized silica ink.

Conventional ball milling technique is used to prepare the self healing colloidal silica ink. High purity SiO₂ (99.9+%, 325 mesh, Aldrich chemical company, Inc, Milwaukee, Wis., USA) powder was used as major dielectric filler. Mixture of distilled ethanol and xylene was used as organic vehicle for preparing a dielectric silica ink. The particle dispersion studies were carried out at varying wt. % of dispersant with respect to filler while keeping the dielectric filler loading at fixed vol. %. Fish oil (Arjuna Natural Extracts, Kerala, India) was used as the dispersant whose wt. % was calculated relative to the weight of the dielectric filler.

The dielectric colloidal ink was prepared in a two stage process. In the first stage, dielectric filler SiO₂ was ball milled for 12 hours with Ethanol/Xylene as the solvent and fish oil as the dispersant. In the second stage Polyvinyl Butyral (Butvar B-98) binder was added and milled again for 12-24 hours. The final dielectric silica ink is ready for printing after completion of second stage of milling. The colloidal stability of the silica ink was measured using rheometer (Brookfield, R/S Plus, Massachusetts, USA). The screen printing of dielectric silica ink was done on both flexible Mylar (biaxially-oriented polyethylene terephthalate or BoPET) film and glass plate substrates. A silk screen with mesh size >325 is used in the screen printing. The well-known photoresist masking technique was used to develop the required geometry printing.

The images of printed dielectric layer on Mylar sheet and glass plate was recorded with digital camera (Sony, 10× optical zoom, 16M Pixel). The printing quality of dielectric ink was optimized with the help of optical microscopy (Leica, MRDX). The microstructure of printed layer was studied using scanning electron microscopy at different magnification. The surface roughness of screen printed silica ink over Mylar film was measured using Atomic Force Microscope (AFM) (NTEGRA, NT-MDT, Russia) operating in tapping mode. Micro-fabricated SiN cantilever tip with resonant frequency 300 kHz, curvature radius 10 nm and a force constant 3.08-37.6 Nm⁻¹ were used in AFM. The image scan size of 10 μm×10 μm and scan rate of 1 Hz were fixed for measurement. The RF dielectric measurement of colloidal ink was measured using Hioki LCR meter (HIOKI 3532-50 LCR Hi TESTER, Japan) measurement with dried ink pelletized to form 11 mm×2 mm discs, which were priory electroded in the form of parallel plate capacitors and the measurements were done with an accuracy of <0.2%. The microwave dielectric properties of printed silica ink on flexible substrate were measured in a split post dielectric resonator (SPDR) operating at 15.15 GHz using Vector Network analyzer (8753ET, Agilent Technologies, Santa Clara, Calif.). The temperature variation of relative permittivity at 15.15 GHz with an operating temperature rage 25-60° C. was also measured.

### EXAMPLES

The following examples are given by the way of illustration and therefore should not be construed to limit the scope of the invention.

### Example 1

SiO₂ powders was ball milled for 12 hours, to achieve uniform particle size and preheated at 600° C. for 4 hours to remove the moisture and organic contaminants during ball milling. In the present investigation, equimolar mixture of anhydrous Xylene and Ethanol were used as the solvent. The dielectric colloidal ink was prepared in a two stage process. In the first stage, dielectric filler SiO₂ was ball milled for 12 hours with Ethanol/Xylene solvent, where fish oil was used as the dispersant. In the second stage Polyvinyl Butyral (Butvar B-98) binder was added and milled again for 12 hours. The ready to print dielectric silica ink is obtained only after completion of second stage of milling.

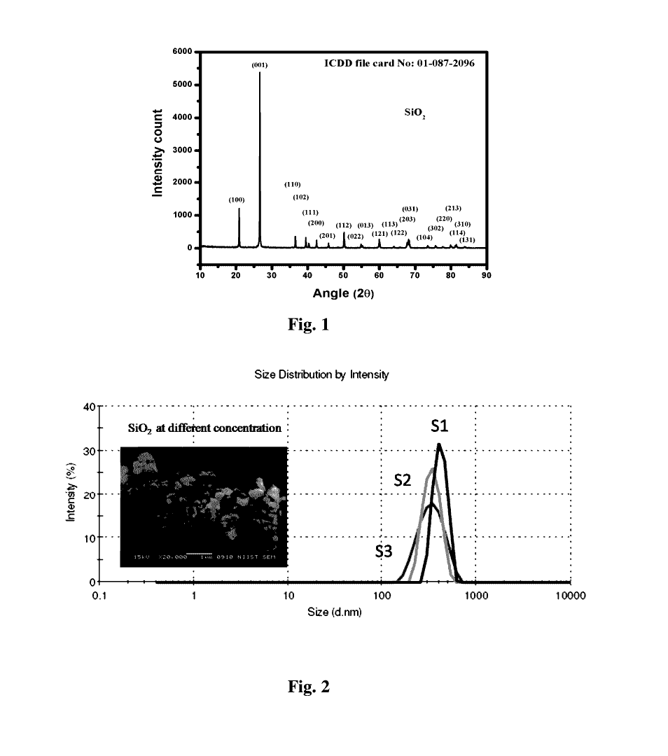

The phase purity of the preheated SiO₂ powder was explained in the FIG. 1. All the peaks corresponding to the X-ray diffraction results are indexed using standard ICDD file card no: 01-087-2096. The peaks were matched to SiO₂ with hexagonal crystal structure with primitive lattice having space group P3221 (154). The particle size analysis of preheated SiO₂ having the average particle size distribution in the range of 100-1000 nm. The inset of FIG. 2 shows the microstructure of the filler particle distribution which was consistent with the particle size distribution determined through Malvern particle size analysis (Zetasizer Nanoseries: ZEN 3600, Malvern Worcestershire, UK).

### Example 2

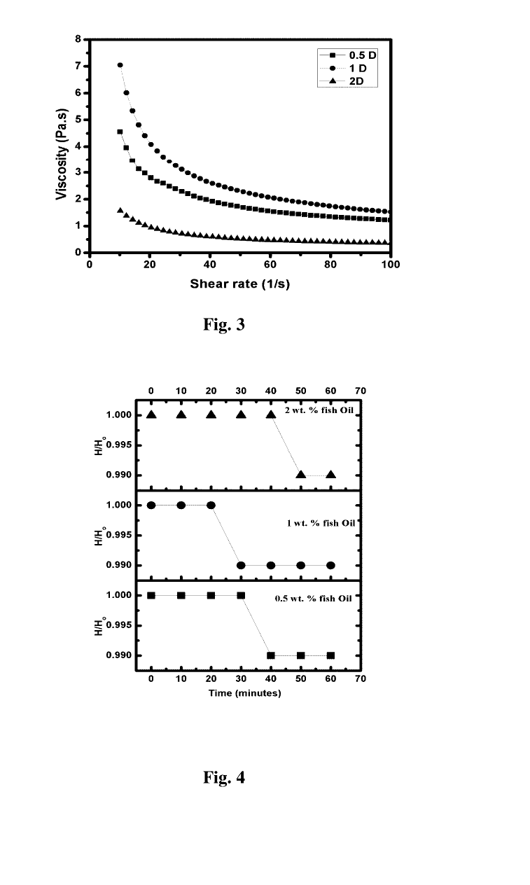

This example illustrates the optimization of fish oil by rheology as well as sedimentation analysis. The filler was ball milled in the solvent with dispersant for 12 hours. The shear viscosity of the resultant colloidal mixture was measured using a rheometer. The viscosity of the well dispersed colloidal mixture was lower and also maintained the average viscosity for screen printing i.e >2 Pa·s. FIG. 3 shows the variation of viscosity with shear rate of colloidal mixture prepared by loading 35 vol. % SiO₂ in the Ethanol/Xylene organic vehicle for different amounts of fish oil dispersant. The viscosity of colloidal mixture decreased with increase in shear rate and maintained the pseudoplastic nature of the screen printing ink.

For sedimentation analysis, 10 ml of the colloidal mixture was transferred into graduated measuring cylinder and allowed to settle. The sediment height (H) was then measured at regular intervals of time and the ratio of sediment height to the initial height (H/Ho) was calculated. FIG. 4 shows the relative sediment height of suspensions containing 35 vol. % of SiO₂ for varying amount of dispersant as a function of time. The colloidal suspension containing 1 wt. % of dispersant has highest rate of sedimentation.

### Example 3

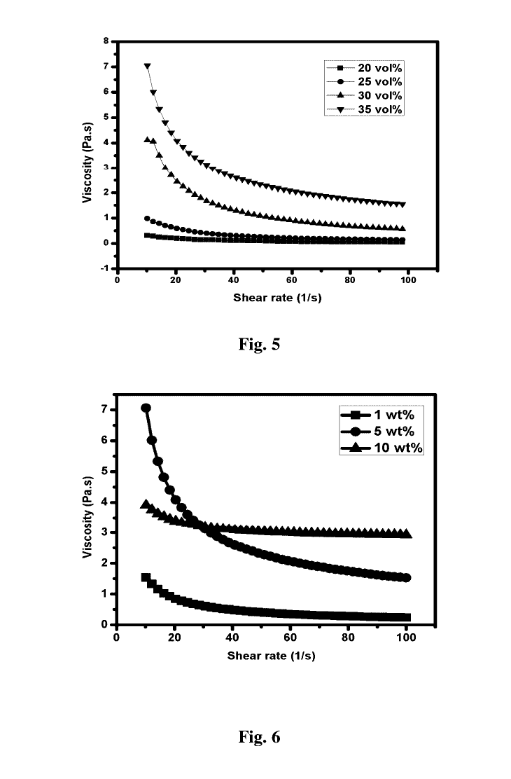

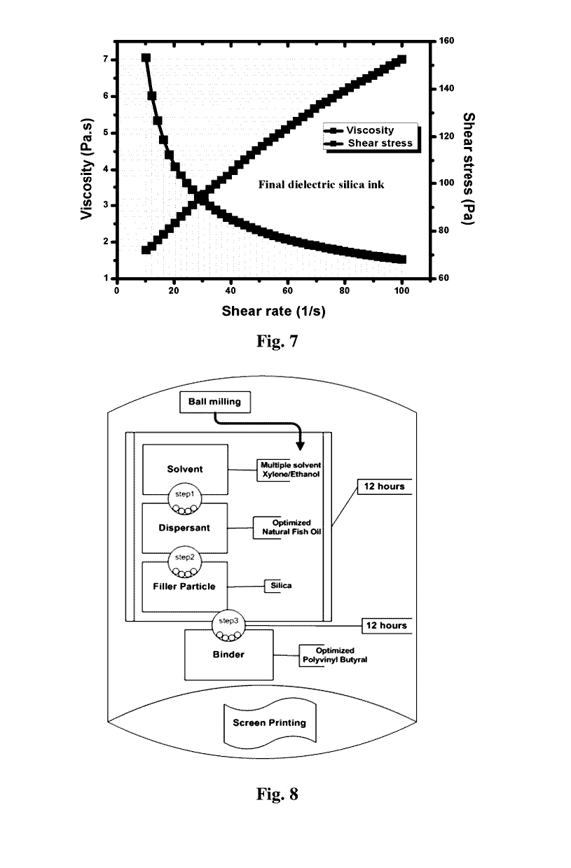

This example illustrates the filler and binder optimization of dielectric silica ink. In the first stage process, the volume ratio between filler and solvent is 35:65. Dispersant and binder were added 1-3 wt. %, 4-7 wt. % respectively with respect to filler loading. The rheological studies were performed at various filler loading from 20 to 35 vol. % with respect to fixed dispersant and binder contents. For optimizing the rheology, the concentrations of the dispersant (fish oil) and binder (PVB) were fixed arbitrarily with respect to the filler loading. A shear thinning behavior of the colloidal dielectric ink can be observed in FIG. 5 which shows the variation of viscosity with respect to the shear rate. This study concluded that the maximum loading of filler was only 35 vol. % and any further increase in the filler content may lead to clogging. A well known polymer polyvinyl butyral (PVB) was used as the binder which satisfies the quality of ink properties such as strength, flexibility, plasticity, lamination, durability and printability. In order to get an optimized binder, filler and dispersant was kept constant and varied the binder content from 1 to 10 wt. % with respect to the maximum filler loading. The maximum viscosity was achieved at 5 wt. % of binder at low shear rate which is shown in FIG. 6. The rheology of the final dielectric silica ink after optimizing the sedimentation, solid loading, viscosity and binder concentration is shown in FIG. 7. The optimized final composition of silica dielectric ink developed in this study prior to screen printing is given in the table 1.

TABLE 1
Final ink composition in weight percentage.

| Contents | | | Ink composition wt % | | |
|---|---|---|---|---|---|
| Filler | Dispersant | Binder | Filler | Dispersant | Binder |
| SiO₂ | Fish oil | Poly Vinyl | 55-65 | 0.8-1.2 | 4-6 |
| | | Butyral | | | |

| | |
|---|---|
| Solvent: Absolute Ethanol/Xylenes | 30-40 |

### Example 4

This example illustrates the various steps in the formulation of dielectric silica ink which is given in FIG. 8. In the first step, dispersant was dissolved in solvent system. The second step comprises the addition of filler material of the functional ink to the resultant mixture obtained in step 1. A continues ball milling for 12-24 hours was required to achieve a stable dispersion with necessary colloidal suspension of the dielectric ink. The third step was to add the binder to the resultant colloidal suspension with subsequent ball milling for another 12-24 hours. A minimum milling time of 24 hours and a maximum milling time of 48 hours is required for the complete preparation of dielectric silica ink. The final dielectric ink can be directly used for screen printing on flexible as well as hard substrates.

### Example 5

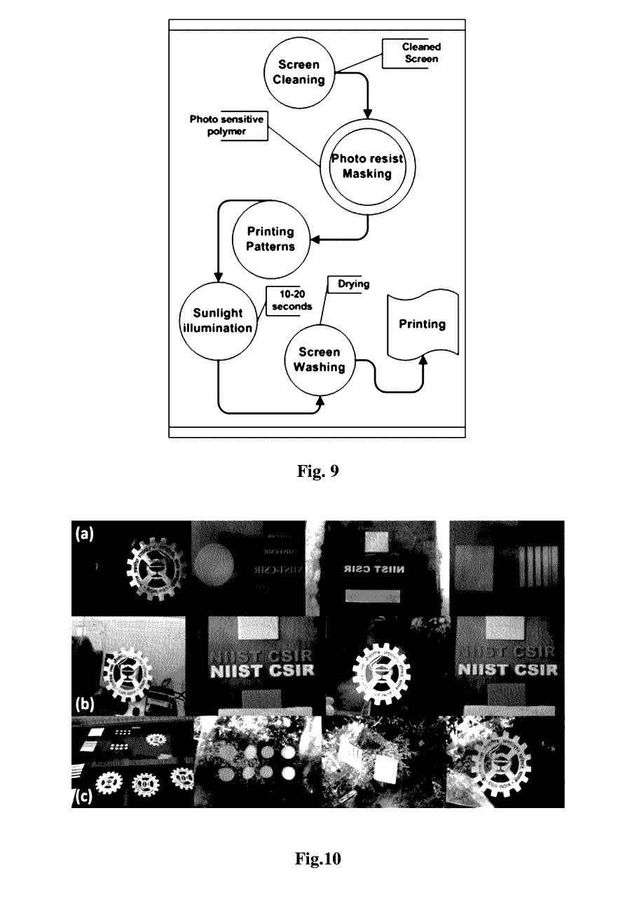

This example illustrates the development stages of screen for screen printing process which is shown in FIG. 9. A silk screen with mesh size >325 which was tightly bound over a metallic frame of dimension 220 mm×170 mm, was used as the screen. First step was to clean the screen with acetone which is subsequently dried with hot air gun at 60° C. Second step was to coat the photoresist on entire screen to mask the meshes and dry it at dark room. The required geometry patterns were designed with suitable design tools which are printed on a transparent sheet. This designed transparent film was then pasted onto the screen that was previously coated with Photoresist material. Finally the screen was exposed to sunlight for 5-10 seconds, followed by washing in running water and dried it for screen printing of desired geometric pattern.

### Example 6

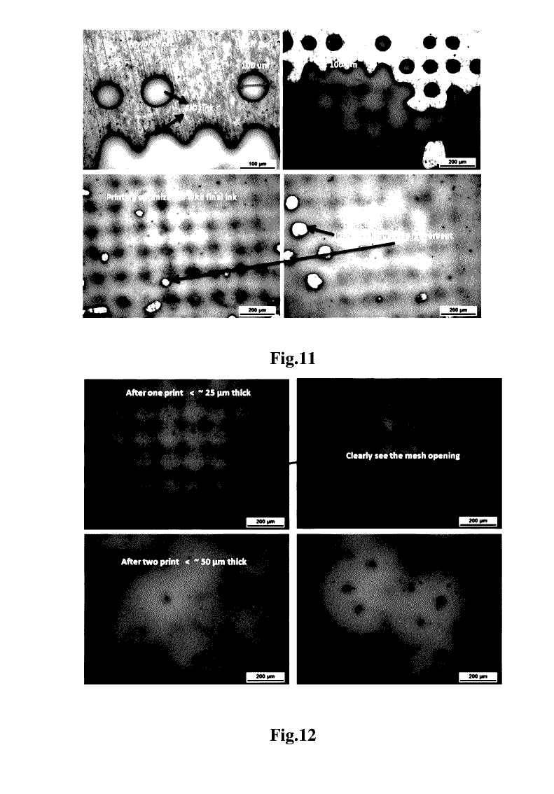

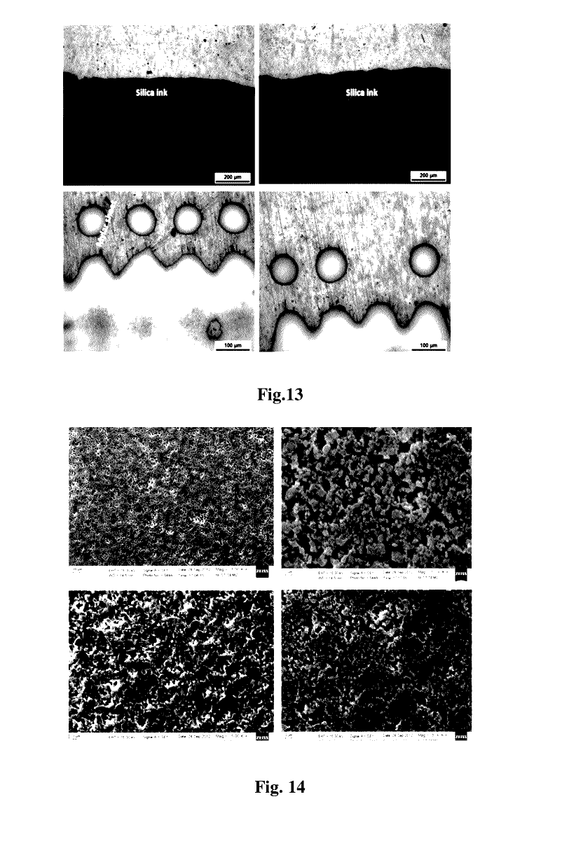

This example illustrates the screen printed dielectric silica. The final dielectric ink was screen printed both on glass plates and flexible Mylar. The different photographic images of screens are shown in the FIG. 10a. Printed patterns over glass plates are shown in the FIG. 10b. Printed geometries on flexible Mylar film are shown in the FIG. 10c. The surface morphology of screen printed silica ink was recorded using optical microscopy and is given in the FIG. 11, FIG. 12 and FIG. 13. The printing optimization stages are clearly indicated in optical microscopic images in the FIG. 11. The printed patterns of the final dielectric silica ink composition printed on Mylar substrate, during printing optimizations are shown in the optical micrographs of FIG. 11. From the optical images one can clearly distinguish the silica ink and Mylar film separately. On examining the optical images, a minor spreading of ink on printing can be visualized which is mainly due to the varying squeegee movement during the printing. Distorted printing and mesh openings are also evident from the surface imaging. In manual screen printing, screen fixing and squeegee movements are critical for better print quality. From the FIG. 12 it was clear that after one print, mesh opening are clearly visible where the printed silica has thickness of about 25 μm. The thickness of printed silica can be controlled by introducing multiple printing steps. The printed thickness of about 50 μm due to two step printing was shown in the FIG. 12. The interface of Mylar and screen printed silica ink was clearly marked in the FIG. 13.

### Example 7

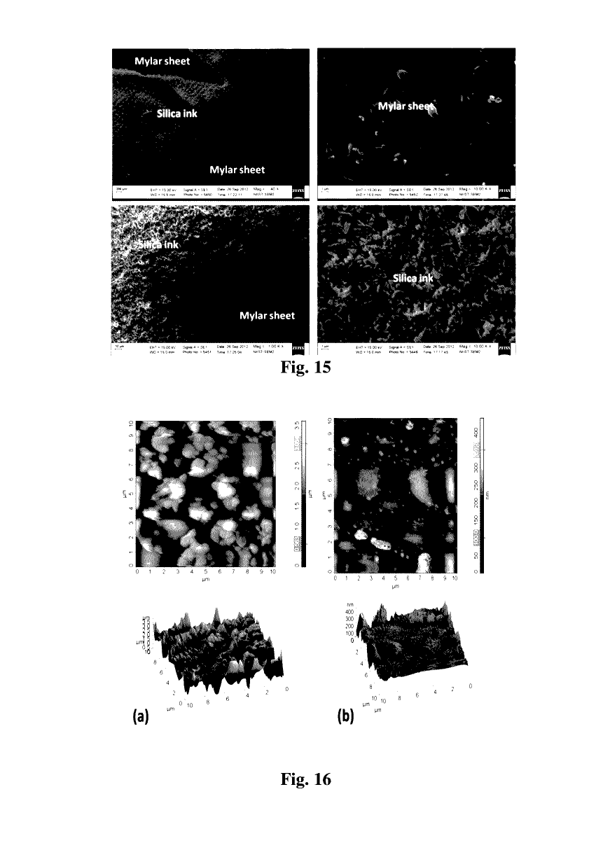

This example illustrates the microstructure of the finally optimized screen printed surfaces and is shown in the FIG. 14. The microstructure presents the screen printed surface with uniformly distributed silica particle having apparently higher porosity. At higher range of magnification, silica crystallites are also visible in the FIG. 14 layer between Mylar substrate and silica ink was clearly visible in the microstructure (FIG. 15). The printed silica layer and Mylar are also visible in the microstructure.

### Example 8

This example illustrates the surface roughness of the screen printed sample measured using Atomic Force Microscopy in tapping mode. The prominently obvious features of the printed surface in 2-D and 3-D surface geometry are shown in FIGS. 16a and 16b. The root mean square (RMS) surface roughness of screen printed silica (see FIG. 16a), Sa was about 370 nm and RMS deviation of surface, Sq was nearly 478 nm. The kurtosis of the topography height distribution (Sku) was nearly 0.546 where as the kurtosis of a well spread distribution was smaller than 3 represents the bumpy surfaces. From the FIG. 16a, it is evident that the surface of printed ink is bumpy in nature of with mountains and valleys. Skewness of topographic height distribution (Ssk) is a measure of asymmetry of the surface deviations about a reference plane. The Ssk of printed silica was ˜−0.089, where the negative value of skewness generally indicates that the surface distribution has a longer tail at the lower side of the reference plane. The surface imaging of Mylar was shown in the FIG. 16b. The difference in the roughness of Mylar film and printed silica ink was clear from the 2-D and 3-D profile images of Mylar sheet and ink printed on Mylar. The RMS surface roughness Sa of Mylar film was of the order ˜21 nm. Detailed comparison of roughness and other surface parameters are given in the table 2.

TABLE 2
Comparison of surface properties of printed dielectric silica ink and
Mylar sheet.

| | Silica ink printed | | | |
|---|---|---|---|---|
| Surfaces | On mylar sheet | | Mylar sheet | |
| Scan area | 10 × 10 | μm | 10 × 10 | μm |
| Average | 370 | nm | 21 | nm |
| Roughness, Sa | | | | |
| Root Mean | 478 | nm | 32 | nm |
| Square, Sq | | | | |

| | | |
|---|---|---|
| Surface | −0.089 | 0.416 |
| skewness, Ssk | | |
| Coefficient of | 0.546 | 5.589 |
| kurtosis, Sku | | |

### Example 9

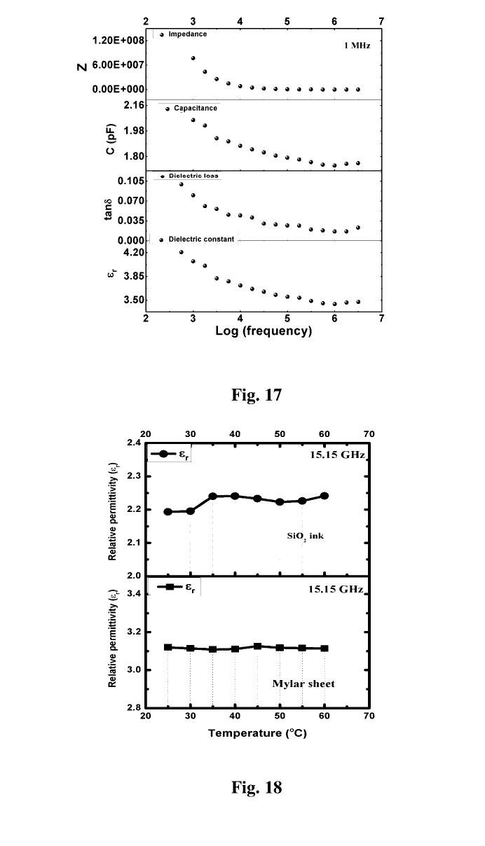

The radio frequency dielectric properties of dielectric ink were measured at 1 MHz using LCR meter. For this measurement, the dielectric ink were dried and ground well to make ceramic disc of dimension 11 mm×2 mm. The variation of relative permittivity (∈ᵣ), capacitance (Cp), impedance (Z) and dielectric loss (tan δ) with radiofrequency range 300 to 3 MHz are shown in the FIG. 17. The dielectric properties decrease with increase in frequency. The dielectric silica ink shows the relative permittivity ∈ᵣ=2.4-3.8 and tan δ=0.01-05 at 1 MHz. The microwave dielectric property of printed dielectric silica ink was measured using SPDR at 15.15 GHz. Dielectric silica ink printed on Mylar sheet shows the relative permittivity ∈ᵣ=2.0-2.8 and tan δ=0.002-0.006 at this frequency. It should be noted that the dielectric constant of the printed silica ink, 2.4 at 15.15 GHz is lower than that of pure SiO₂ (4-5) measured at radio frequency. This discrepancy is believed to be due to the organic vehicle used in the colloidal ink and also the porosity occurred after screen printing. The variation of relative permittivity of silica ink and Mylar substrate with respect to operating temperature was shown in the FIG. 18. The dielectric silica ink showed very little variation of relative permittivity 55-65 ppm/° C. with temperature due to its poor surface roughness.

### Advantages of the Invention

1) The dielectric silica ink was developed for flexible printed electronic applications.
2) The silica ink is more advantageous over water based dielectric inks in terms of faster curing at room temperature.
3) The low relative permittivity of the developed silica ink is achieved after curing.
4) The polymer binder system employed in the ink formulation is highly stable and do not degrade the chemico-physical properties of the silica ink.
5) The number of processing steps is less and cost of production is lower since cost effective solvents, binder and dispersants are employed for the synthesis of the ink. These two aspects are ideal for high volume production of the silica dielectric ink.
6) The developed silica ink showed only very small variation of relative permittivity with respect to temperature, when printed on a flexible substrate.
7) Long shelf life, ideal flow characteristics and high colloidal stability of the developed ink are achieved.
8) The colloidal ink is suitable for printing on hard as well as flexible substrates.
9) Accurate registration and multiple layer printing are established for the developed silica ink.
10) An easy production step to prepare dielectric silica ink, where in cost effective dispersants and solvents are employed.
11) The present invention of silica ink has less waste as compared to the traditional lithographic process.

1. A self healing silica based dielectric ink comprising:
85-95 wt. % silica based colloidal suspension,
0.8-1.2 wt. % dispersant, and
5-15 wt. % polymeric binder,
wherein said ink is useful for flexible printed electronic applications.

2. The self healing silica based dielectric ink as claimed in claim 1, wherein silica based dielectric ink exhibit the relative permittivity (k) ∈ᵣ in the range of 2.4 to 3.8 and 2.0 to 2.8 and dielectric loss (tan δ) in the range of 0.01 to 0.05 and 0.002 to 0.006 at 1 MHz and at 15.15 GHz respectively.

3. The self healing silica based dielectric ink as claimed in claim 1, wherein the silica based dielectric ink shows temperature variation of relative permittivity in the range 55-65 ppm/° C. at operating temperature 25 to 60° C.

4. A process for the preparation of silica based dielectric ink as claimed in claim 1, comprising the steps of:
i. preheating SiO2 powder at 400 to 700° C. for 3 to 5 hours to obtain a preheated SiO₂ powder;
ii. ball milling the 55 to 65 wt. % preheated SiO2 powder for a period in the range of 12 to 24 hours with 30-40 wt. % solvent and 0.8-1.2 wt. % dispersant to obtain a ball milled mixture; and
iii. adding 4-6 wt. % binder in the ball milled mixture as obtained in step (ii) followed by milling for 12-24 hours to obtain silica based dielectric ink.

5. The process as claimed in claim 4, wherein solvent is selected from ethanol or xylene.

6. The process as claimed in claim 4, wherein the dispersant is fish oil.

7. The process as claimed in claim 4, wherein the binder is Polyvinyl Butyral (Butvar B-98).

8. The self healing silica based dielectric ink as claimed in claim 1, wherein viscosity of the ink with respect to shear rate is in the range of 1.5 to 10 Pa·s.
